(19) United States
(12) Patent Application Publication
(10) Pub. No.: US 2026/0006827 A1
(43) Pub. Date: Jan. 1, 2026

(54) SEMICONDUCTOR DEVICE

(71) Applicant: Mitsubishi Electric Corporation, Tokyo (JP)

(72) Inventor: Tetsuo TAKAHASHI, Tokyo (JP)

(73) Assignee: Mitsubishi Electric Corporation, Tokyo (JP)

(21) Appl. No.: 19/098,433

(22) Filed: Apr. 2, 2025

(30) Foreign Application Priority Data
Jun. 26, 2024 (JP) 2024-102903

(51) Int. Cl. H10D 30/66; H10D 30/01; H10D 62/10; H10D 62/60

(52) U.S. Cl. CPC H10D 30/662; H10D 62/102; H10D 62/124; H10D 62/60; H10D 30/0291

(57) ABSTRACT

A semiconductor device includes a drift layer of a first conductivity type, a channel layer of a second conductivity type, a source layer of the first conductivity type, a gate electrode, a source electrode, and a drain electrode. In a case where an impurity concentration of the drift layer is different in the drift layer, an integral value of an electric field applied to the drift layer is set as a withstand voltage value, and an integral value of an electric field in a case where the impurity concentration of the drift layer is constant in the drift layer is set as a reference value, (the withstand voltage−the reference value)/the reference value is equal to or greater than 0 and equal to or less than 0.32.

### BACKGROUND

### Technical Field

The technology disclosed in the present specification relates to a semiconductor technology.

### Description of the Background Art

In a semiconductor device, a withstand voltage and an on-resistance have a trade-off relationship using a thickness and concentration of a drift layer as parameters. Thus, a technology for simultaneously improving these two characteristics is required (see, for example, Japanese Patent Application Laid-Open No. 2010-232355).

However, in the technology of Japanese Patent Application Laid-Open No. 2010-232355, the trade-off relationship between the withstand voltage and the on-resistance is not sufficiently improved, and there is room for improvement.

### SUMMARY

The technology disclosed in the present specification is a technology for improving a trade-off relationship between a withstand voltage and an on-resistance of a semiconductor device.

A semiconductor device according to a first aspect of the technology disclosed in the present specification includes: a drift layer of a first conductivity type; a channel layer of a second conductivity type that is above the drift layer; a source layer of the first conductivity type that is above the channel layer; a gate electrode facing the channel layer sandwiched between the drift layer and the source layer via a gate insulating film; a source electrode connected to the source layer; and a drain electrode on a lower surface side of the drift layer. An impurity concentration of the drift layer is different in the drift layer, and in a case where an integral value of an electric field applied to the drift layer is set as a withstand voltage value, and an integral value of an electric field in a case where the impurity concentration of the drift layer is constant in the drift layer is set as a reference value, (the withstand voltage value−the reference value)/the reference value is equal to or greater than 0 and equal to or less than 0.32.

As a result of an increase in the withstand voltage value/the reference value being equal to or greater than 0 and equal to or less than 0.32, a trade-off relationship between a withstand voltage and an on-resistance of the semiconductor device can be improved as compared with a case where the impurity concentration of the drift layer is constant.

Further, objects, features, aspects, and advantages relating to the technology disclosed in the present specification will be more apparent from the following detailed description and the accompanying drawings.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating an example of a configuration of a semiconductor device according to a preferred embodiment;

FIG. 2 is a plan view illustrating an example of a configuration of a region that is part of an active region in FIG. 1;

FIG. 3 is a cross-sectional view illustrating an example of an A-A′ cross section in FIG. 2;

FIG. 4 is a view indicating an example of an impurity concentration profile along a B-B′ cross section in FIG. 3;

FIG. 5 is a view indicating an example of electric field distribution of the B-B′ cross section in FIG. 3 at the time of OFF;

FIG. 6 is a view indicating an example of electric field distribution generated by an n− drift layer at the time of OFF;

FIG. 7 is a view indicating a modification of the impurity concentration profile along the B-B′ cross section in FIG. 3;

FIG. 8 is a view indicating an example of an electric field distribution generated by the n− drift layer indicated in FIG. 7 at the time of OFF;

FIG. 9 is a view indicating a boundary at which both improvement in a withstand voltage and reduction in an on-resistance of a 600 V-class device are achieved when a thickness of a drift layer is set at 5.5 μm;

FIG. 10 is a view indicating a boundary at which both improvement in a withstand voltage and reduction in an on-resistance of a 1200 V-class device are achieved when the thickness of the drift layer is set at 10 μm;

FIG. 11 is a view indicating a boundary at which both improvement in a withstand voltage and reduction in an on-resistance of a 1700 V-class device are achieved when the thickness of the drift layer is set at 15 μm;

FIG. 12 is a view illustrating an example of a method of manufacturing the semiconductor device according to the preferred embodiment;

FIG. 13 is a view illustrating an example of the method of manufacturing the semiconductor device according to the preferred embodiment;

FIG. 14 is a view illustrating an example of the method of manufacturing the semiconductor device according to the preferred embodiment;

FIG. 15 is a view illustrating an example of the method of manufacturing the semiconductor device according to the preferred embodiment;

FIG. 16 is a cross-sectional view illustrating a modification of the A-A′ cross section in FIG. 2 according to the preferred embodiment;

FIG. 17 is a view indicating an example of an impurity concentration profile along a C-C′ cross section in FIG. 16;

FIG. 18 is a cross-sectional view illustrating a modification of the A-A′ cross section in FIG. 2 according to the preferred embodiment;

FIG. 19 is a view indicating an example of an impurity concentration profile along a D-D′ cross section in FIG. 18;

FIG. 20 is a cross-sectional view illustrating a modification of the A-A′ cross section in FIG. 2 according to the preferred embodiment;

FIG. 21 is a view indicating an example of an impurity concentration profile along an E-E′ cross section in FIG. 20;

FIG. 22 is a cross-sectional view illustrating a modification of the A-A′ cross section in FIG. 2 according to the preferred embodiment;

FIG. 23 is a view indicating an example of an impurity concentration profile along an F-F′ cross section in FIG. 22;

FIG. 24 is a plan view illustrating an example of a configuration of an insulated gate semiconductor device according to a comparative example;

FIG. 25 is a plan view illustrating an example of a configuration of a region that is part of an active region in FIG. 24;

FIG. 26 is a cross-sectional view illustrating an example of a G-G′ cross section in FIG. 25;

FIG. 27 is a view indicating an example of an impurity concentration profile along an H-H′ cross section in FIG. 26;

FIG. 28 is a view indicating an example of an electric field distribution of an H-H′ cross section in FIG. 26 at the time of OFF;

FIG. 29 is a view indicating an example of voltage distribution of the H-H′ cross section in FIG. 26 at the time of OFF; and

FIG. 30 is a view indicating an example of a resistance value in an n− drift layer.

### DESCRIPTION OF THE PREFERRED EMBODIMENTS

Hereinafter, preferred embodiments will be described with reference to the accompanying drawings. In the following preferred embodiments, detailed features, and the like, are also indicated for explaining the technology, but they are merely examples, and not all of them are necessarily essential features to carry out the preferred embodiments.

Note that the drawings are schematically illustrated, and omission of components, simplification of a configuration, or the like, is appropriately made in the drawings for convenience of description. In addition, a mutual relationship of sizes and positions of components, and the like, illustrated in different drawings is not necessarily accurately described, and can be appropriately changed. In addition, hatching may be applied to a drawing such as a plan view that is not a cross-sectional view in order to facilitate understanding of the content of the preferred embodiments.

Furthermore, in the following description, similar components are denoted by the same reference numerals, and names and functions thereof are also similar. Thus, detailed description thereof may be omitted in order to avoid duplication.

In addition, in the description described in the present specification, description of “comprising”, “including”, “having”, or the like, a certain component is not exclusive expression excluding the presence of other components unless otherwise specified.

In addition, in the description described in the present specification, even if ordinal numbers such as “first” or “second” are used, these terms are used for convenience to facilitate understanding of the content of the preferred embodiments, and the content of the preferred embodiments is not limited to the order, or the like, that can be caused by these ordinal numbers.

Furthermore, in the description described in the present specification, even if terms meaning specific positions or directions such as “upper”, “lower”, “left”, “right”, “side”, “bottom”, “front”, or “back” are used, these terms are used for convenience to facilitate understanding of the content of the preferred embodiments, and are not related to the positions or directions when the preferred embodiments are actually implemented.

Furthermore, in the description described in the present specification, the description of “the upper surface of . . . ”, “the lower surface of . . . ”, or the like, includes a state in which another component is formed on the upper surface or the lower surface of the target component in addition to the upper surface itself or the lower surface itself of the target component. In other words, for example, description of “B provided on the upper surface of A” does not exclude interposition of another component “C” between A and B.

### First Preferred Embodiment

Hereinafter, a semiconductor device according to a present preferred embodiment will be described.

### <Configuration of Semiconductor Device>

A power semiconductor device generally called a power device is used for a switching element that controls power supply such as a motor load. Various kinds of performance are required for the power device, and one of them is low loss.

Reduction of a loss of the power device has effects of making the device smaller or lighter, and includes an effect that eventually leads to consideration for a global environment by reducing energy consumption. Furthermore, it is desired that these characteristics be implemented at the lowest possible cost.

As a power semiconductor element satisfying these requirements, an insulated gate semiconductor device such as an insulated gate bipolar transistor (IGBT) or a metal oxide semiconductor field effect transistor (MOSFET) is widely used, and in recent years, a MOSFET, an IGBT, or the like, using a wide band gap semiconductor such as silicon carbide (SiC) has been proposed.

A MOSFET using silicon carbide is a device capable of achieving both a low on-resistance and holding of a high main withstand voltage, and is a monopolar device, and thus, its application has been expanded to high-speed switching applications.

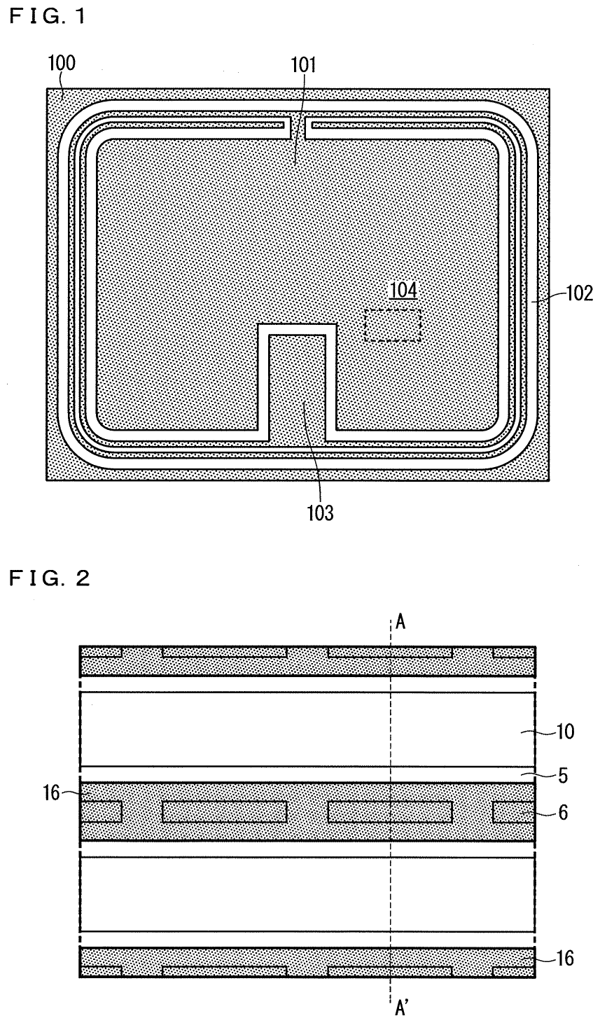

FIG. 1 is a plan view illustrating an example of a configuration of a semiconductor device according to the present preferred embodiment. As illustrated in the example in FIG. 1, in an element region 100, an active region 101, a gate wiring 102 (withstand voltage holding region) formed to surround the active region 101, and a gate pad region 103 (control electrode) so as to be in contact with the active region 101 are formed.

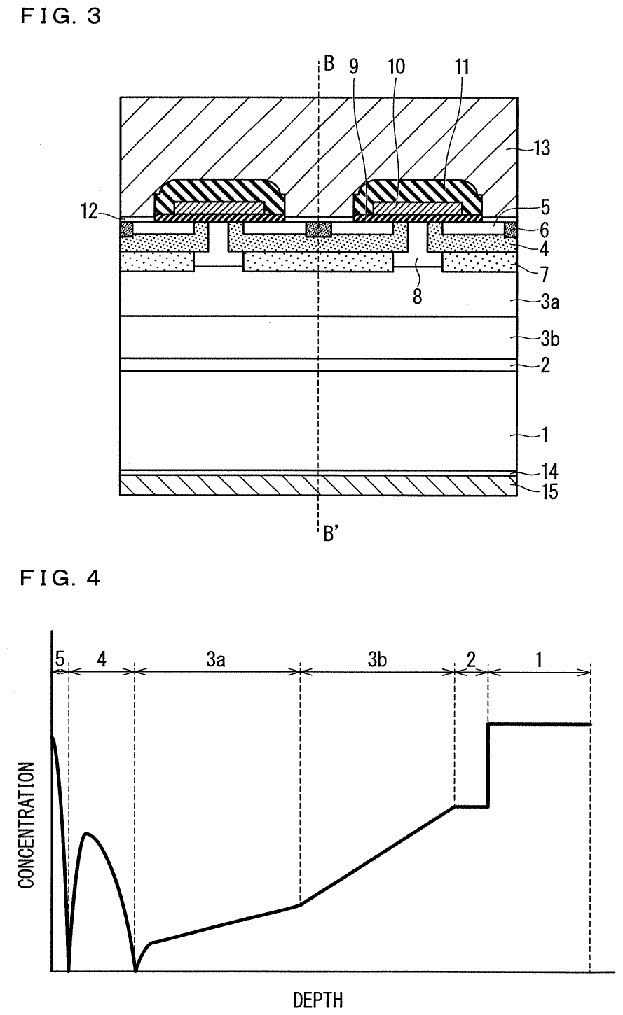

FIG. 2 is a plan view illustrating an example of a configuration of a region 104 which is part of the active region in FIG. 1. In FIG. 2, a source electrode contact region 16 is illustrated. Further, FIG. 3 is a cross-sectional view illustrating an example of an A-A′ cross section in FIG. 2.

As illustrated in the examples of FIGS. 2 and 3, an n+ buffer layer 2 is formed on an upper surface of an n+ semiconductor substrate 1 made of silicon carbide (SiC). Then, an n− drift layer 3b is formed on an upper surface of the n+ buffer layer 2, and an n− drift layer 3a is further formed on an upper surface of the n− drift layer 3b.

In addition, an n-type junction field effect transistor (nJFET) doped layer 8 is formed above the n− drift layer 3a, and a p-channel doped layer 4 is formed above the nJFET doped layer 8. A p-well layer 7 is formed below the p-channel doped layer 4.

In addition, an n+ source layer 5 is formed above the p-channel doped layer 4, and a p+ contact layer 6 is formed so as to be surrounded by the n+ source layer 5 above the p-channel doped layer 4.

In addition, a gate electrode 10 made of polysilicon, or the like, faces the p-channel doped layer 4 sandwiched between the n+ source layer 5 and the nJFET doped layer 8 (an upper layer of the n− drift layer 3a) via a gate insulating film 9. An interlayer insulating film 11 is formed to cover the gate electrode 10. A source electrode 13 is connected to the n+ source layer 5 and a p+ contact layer 6 via a silicide layer 12.

In addition, a silicide layer 14 is formed on a lower surface of the n+ semiconductor substrate 1, and a drain electrode 15 is formed on a lower surface of the silicide layer 14.

In FIG. 3, a basic cell structure of an active region is illustrated. The source electrode 13 is formed on an upper surface side of the substrate, and a drain electrode 18 is formed on a lower surface side of the substrate. Then, a main current flows in a vertical direction of the substrate. In addition, a MOSFET including the n+ source layer 5, the p-channel doped layer 4, the drift layer (the n− drift layer 3a and the n− drift layer 3b), the gate insulating film 9, and the gate electrode 10 performs gate control of a current.

In addition, the n+ buffer layer 2 is a region formed of high-concentration n-type impurities so that holes do not reach the n+ semiconductor substrate 1 during FWD operation of the device. In principle, when a depletion layer extends, the n+ buffer layer 2 is partially depleted and shares a voltage. However, the n+ buffer layer 2 is set so as to have a high concentration and share a voltage lower than that of the drift layer (n− drift layer 3a and n− drift layer 3b), and thus, the n+ buffer layer 2 will not be described in the following discussion.

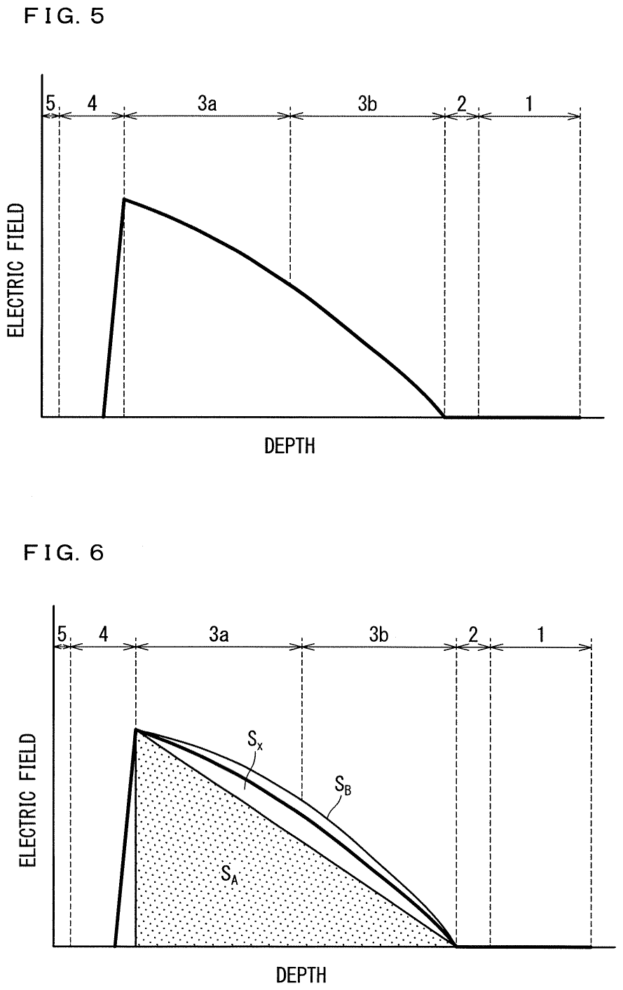

FIG. 4 is a view indicating an example of an impurity concentration profile along a B-B′ cross section in FIG. 3. In FIG. 4, a vertical axis represents an impurity concentration, and a horizontal axis represents a depth. FIG. 5 is a view indicating an example of electric field distribution along the B-B′ cross section in FIG. 3 at the time of OFF. FIG. 6 is a view indicating an example of electric field distribution generated by the n− drift layer 3a and the n− drift layer 3b at the time of OFF. In FIGS. 5 and 6, a vertical axis represents electric field intensity, and a horizontal axis represents a depth.

In the present preferred embodiment, as indicated in the example in FIG. 4, the drift layer includes the n− drift layer 3a and the n− drift layer 3b having two types of concentration inclinations, and the electric field intensity is as indicated in FIG. 5.

Here, referring to FIG. 6, an area corresponding to an integral value of the electric field intensity generated in a range where the n− drift layer 3a and the n− drift layer 3b are formed will be examined. The integral value of the generated electric field intensity matches an applied voltage, and a value of the voltage (an integral value of the electric field intensity, a withstand voltage area) corresponding to critical electric field intensity causing avalanche breakdown is generally referred to as a withstand voltage (withstand voltage value).

In the range where the n− drift layer 3a and the n− drift layer 3b are formed, an area of a triangle surrounded by a line connecting the critical electric field intensity at a boundary position between the n− drift layer 3a and the p-channel doped layer 4 and electric field intensity (0) at a boundary position between the n− drift layer 3b and the n+ buffer layer 2 and a line on which electric field intensity is 0 is set as S_{A}. This S_{A} is an area corresponding to the integral value of the electric field intensity in a case where the impurity concentration is constant throughout the drift layer (in a case where there is no concentration change), and is also referred to as a reference area (reference value). In FIG. 6, the electric field intensity applied to the n− drift layer 3a and the n− drift layer 3b is higher than that in a case of the reference value in the entire region, and the withstand voltage value increases more than the reference value.

Furthermore, an area obtained by subtracting S_{A} from the above-described withstand voltage area (withstand voltage value) is defined as S_{X}. In addition, in a case where an increase in the withstand voltage value (an increase in the withstand voltage) in the electric field distribution that is a limit for improving the trade-off relationship between the withstand voltage and the on-resistance is set as S_{B}, S_{X} is included within the range of S_{B} satisfying S_{B}≤0.32S_{A} (conditional expression 1). The conditional expression 1 will be described later in detail.

Further, in the present preferred embodiment, as exemplified in FIG. 4, the impurity concentration of the n− drift layer 3a is set lower than the impurity concentration of the n− drift layer 3b.

In the present preferred embodiment, as indicated in the example in FIG. 4, a concentration gradient of the n− drift layer 3a is set to be lower than a concentration gradient of the n− drift layer 3b.

Here, a comparative example will be described.

FIG. 24 is a plan view illustrating an example of a configuration of an insulated gate semiconductor device (MOSFET) according to the comparative example. As illustrated in the example in FIG. 24, in the element region 100, the active region 101, the gate wiring 102 formed to surround the active region 101, and the gate pad region 103 formed outside the active region 101 are formed.

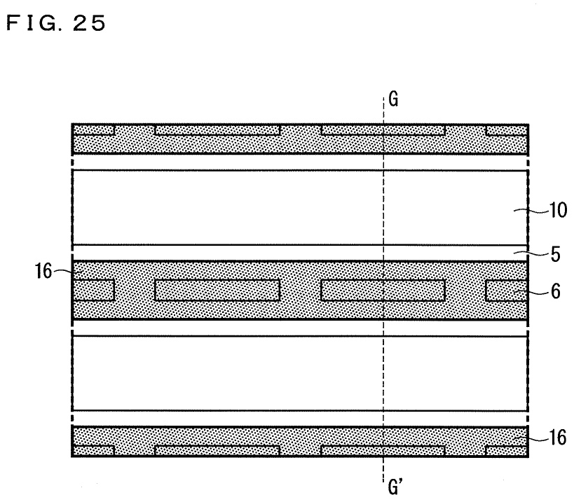

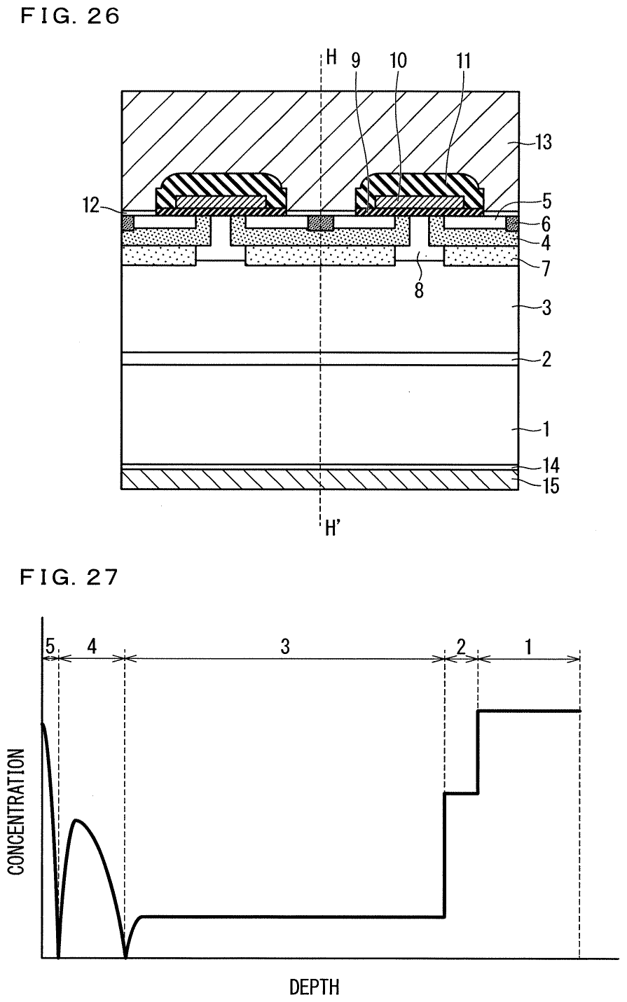

FIG. 25 is a plan view illustrating an example of a configuration of the region 104 that is part of the active region in FIG. 24. In FIG. 25, the source electrode contact region 16 is illustrated. FIG. 26 is a cross-sectional view illustrating an example of a G-G′ cross section in FIG. 25.

As illustrated in the examples of FIGS. 25 and 26, the n+ buffer layer 2 is formed on the upper surface of the n+ semiconductor substrate 1. Then, the n− drift layer 3 is formed on the upper surface of the n+ buffer layer 2.

In addition, the nJFET doped layer 8 is formed above the n− drift layer 3, and the p-channel doped layer 4 is formed above the nJFET doped layer 8. A p-well layer 7 is formed below the p-channel doped layer 4.

In addition, an n+ source layer 5 is formed above the p-channel doped layer 4, and a p+ contact layer 6 is formed so as to be surrounded by the n+ source layer 5 above the p-channel doped layer 4.

In addition, the gate electrode 10 made of polysilicon, or the like, faces the p-channel doped layer 4 sandwiched between the n+ source layer 5 and the nJFET doped layer 8 via the gate insulating film 9. An interlayer insulating film 11 is formed to cover the gate electrode 10. The source electrode 13 is in contact with the n+ source layer 5 and the p+ contact layer 6 via the silicide layer 12.

In addition, a silicide layer 14 is formed on a lower surface of the n+ semiconductor substrate 1, and a drain electrode 15 is formed on a lower surface of the silicide layer 14.

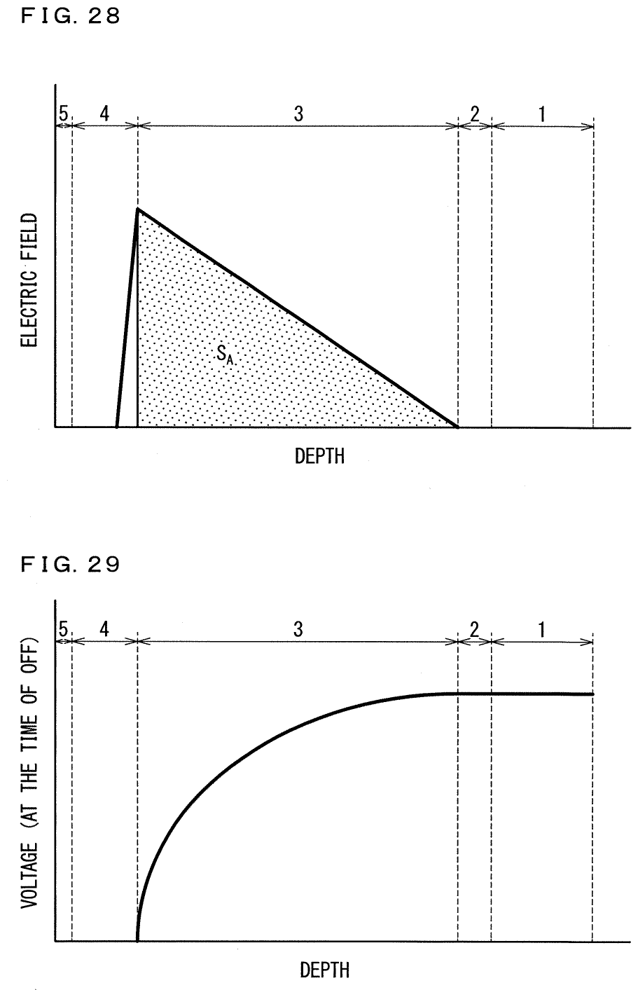

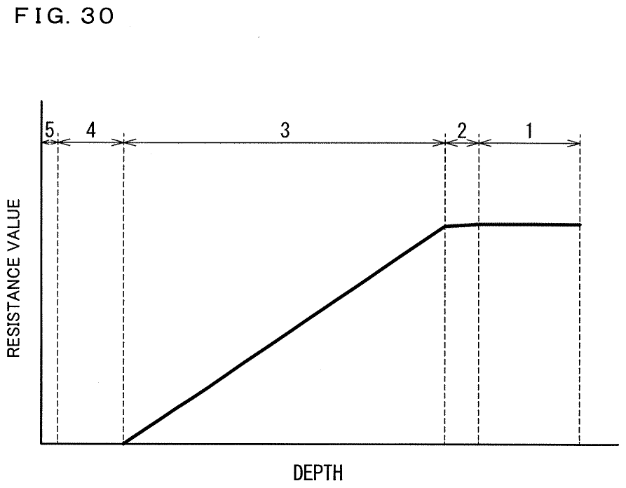

FIG. 27 is a view indicating an example of an impurity concentration profile along an H-H′ cross section in FIG. 26. In FIG. 27, a vertical axis represents an impurity concentration, and a horizontal axis represents a depth. FIG. 28 is a view indicating an example of electric field distribution along the H-H′ cross section in FIG. 26 at the time of OFF. In FIG. 28, a vertical axis represents electric field intensity, and a horizontal axis represents a depth. FIG. 29 is a view indicating an example of voltage distribution along the H-H′ cross section in FIG. 26 at the time of OFF. In FIG. 29, a vertical axis represents voltage intensity, and a horizontal axis represents a depth. FIG. 30 is a view indicating an example of a resistance value in the n− drift layer 3. In FIG. 30, a vertical axis represents the resistance value, and a horizontal axis represents a depth.

First, effects of the present preferred embodiment will be described.

As a premise, the depletion layer also enters the inside of the p-channel doped layer 4 and shares a voltage, but the impurity concentration of the p-channel doped layer 4 is higher than the impurity concentrations of the n− drift layer 3a and the n− drift layer 3b by one digit or more, and thus, the voltage to be shared by the p-channel doped layer 4 side is approximated to 0 for the same reason as a method usually referred to as one-side step junction, and will be described below.

In addition, the n+ semiconductor substrate 1 and the n+ buffer layer 2 also share voltages in principle, but the voltages to be shared are minute compared to amounts of the voltages to be shared by the n− drift layer 3a and the n− drift layer 3b, and thus, the voltages to be shared by the n+ semiconductor substrate 1 and the n+ buffer layer 2 are also approximated to 0, and only the n− drift layer 3a and the n− drift layer 3b will be discussed.

A switching element including an MOSFET needs to have two functions of current cutoff at the time of OFF and energization capability at the time of ON.

The MOSFET (see FIG. 26) implements the functions as a result of a channel of the MOSFET including the n+ source layer 5, the p-channel doped layer 4, and the n− drift layer 3 being turned off when the current is cut off at the time of OFF, and the n− drift layer 3 being depleted thereby the withstand voltage being maintained.

The withstand voltage is mainly determined by a thickness and the impurity concentration of the n− drift layer 3, and the electric field is determined based on the impurity concentration. The withstand voltage is determined by integration of electric fields, and thus, the withstand voltage increases as the impurity concentration of the n− drift layer 3 is lower and the thickness of the n− drift layer 3 is thicker.

On the other hand, at the time of ON, the channel is turned on, and a current flows through the channel. The MOSFET is a monopolar device and does not cause conductivity modulation, and thus, the on-resistance at the time of energization is determined by a sum of components such as channel resistance, drift resistance of the n− drift layer 3, and contact resistance. In this event, the drift resistance is determined by the impurity concentration and the thickness of the n− drift layer 3, and as the impurity concentration of the n− drift layer 3 is lower and the thickness of the n− drift layer 3 is thinner, the resistance becomes lower.

Thus, the withstand voltage and the on-resistance have a trade-off relationship using the thickness and the impurity concentration of the n− drift layer 3 as parameters, so that it is difficult to simultaneously improve these two characteristics.

However, in the present preferred embodiment, as compared with FIG. 27 of the comparative example, as indicated in the example of FIG. 4, the drift layer is formed with two types of the n− drift layer 3a and the n− drift layer 3b, and the impurity concentration and the concentration gradient (change rate of the concentration) of the n− drift layer 3a are set lower than the impurity concentration and the concentration gradient (change rate of the concentration) of the n− drift layer 3b.

In such a case, electric field distribution of the n− drift layer 3a and the n− drift layer 3b in a state where the depletion layer reaches the n+ buffer layer 2 corresponds to a withstand voltage area (S_{A}+S_{X}) having an arcuate arc as indicated in FIGS. 5 and 6, rather than a triangular area (S_{A}) as indicated in FIG. 28. In FIGS. 5 and 6, maximum electric field intensity is the same as that in the comparative example, but the electric field applied to the n− drift layer 3a and the n− drift layer 3b is always higher than the electric field indicating the triangular shape in the comparative example. Thus, the arc of the withstand voltage area protrudes upward.

In the present preferred embodiment, the withstand voltage value corresponding to a height of the withstand voltage is S_{A}+S_{X} that is larger than S_{A}, and thus, the withstand voltage increases even with the same thickness of the drift layer. In other words, as a result of the concentration gradient of the drift layer being formed, the withstand voltage area can be increased by increasing the electric field while maintaining the critical electric field strength. It is therefore possible to increase the withstand voltage.

The electric field distribution having the arcuate arc changes depending on the impurity concentration, the concentration inclination, and the thickness of the n− drift layer 3a and the impurity concentration, the concentration inclination, and the thickness of the n− drift layer 3b, and thus, a higher withstand voltage can be obtained depending on setting of these parameters.

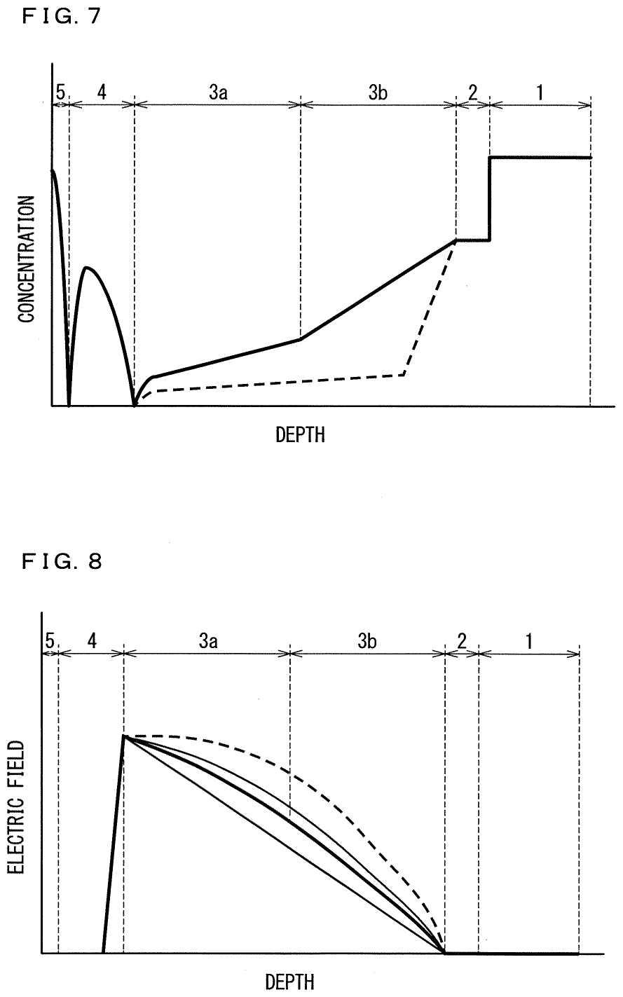

FIG. 7 is a view indicating a modification of the impurity concentration profile along the B-B′ cross section in FIG. 3. In FIG. 7, a vertical axis represents an impurity concentration, and a horizontal axis represents a depth. The impurity concentration profile indicated by a dotted line in FIG. 7 corresponds to a case where the impurity concentration and the concentration inclination of the n− drift layer 3a are set to be low, the thickness of the n− drift layer 3a is set to be thick, the impurity concentration and the concentration inclination of the n− drift layer 3b are set to be high, and the thickness of the n− drift layer 3b is set to be thin, as compared with the case of FIG. 4 (solid line).

FIG. 8 is a view indicating an example of electric field distribution generated by the n− drift layer 3a and the n− drift layer 3b indicated in FIG. 7 at the time of OFF. In FIG. 8, a vertical axis represents electric field intensity, and a horizontal axis represents a depth.

As indicated in FIG. 8 as an example, the withstand voltage value of the electric field intensity (dotted line) corresponding to the impurity concentration profile indicated in FIG. 7 is larger than that of the case indicated in FIG. 6 (solid line). In other words, the withstand voltage in the case indicated in FIG. 8 is higher than the withstand voltage in the comparative example based on the area S_{A} and the withstand voltage in the case indicated in FIG. 6 based on the area S_{A}+S_{X}.

In the case indicated in FIG. 8, although the withstand voltage increases, the on-resistance also increases. Thus, as compared with the case where the thickness of the n− drift layer 3 is increased to achieve the same withstand voltage in the comparative example, the on-resistance may increase, or the on-resistance may increase inversely when the thickness of the substrate is adjusted.

The inventors have found that the region where both increase in the withstand voltage and improvement in the on-resistance are possible is substantially limited, and is limited to the electric field distribution in a range in which the arcuate arc is formed (a range in which the drift layer is formed) as indicated in FIG. 8.

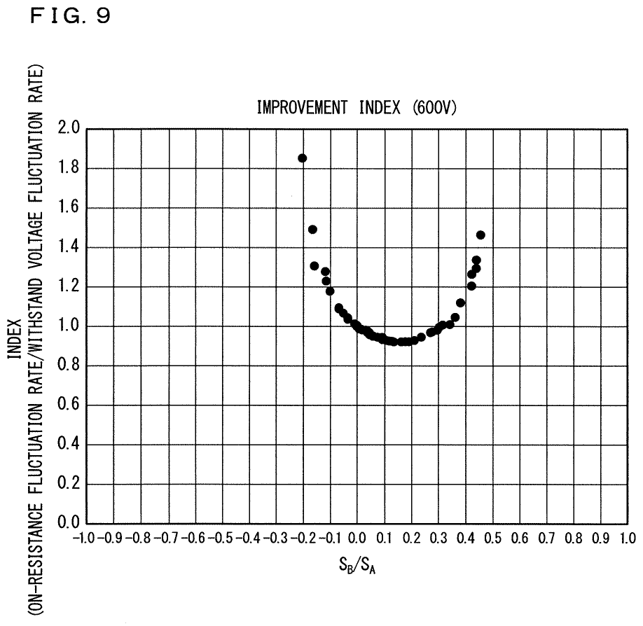

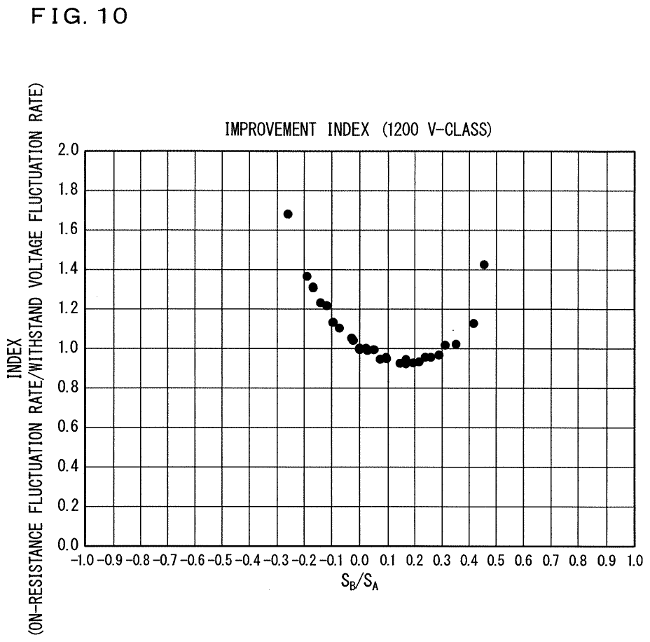

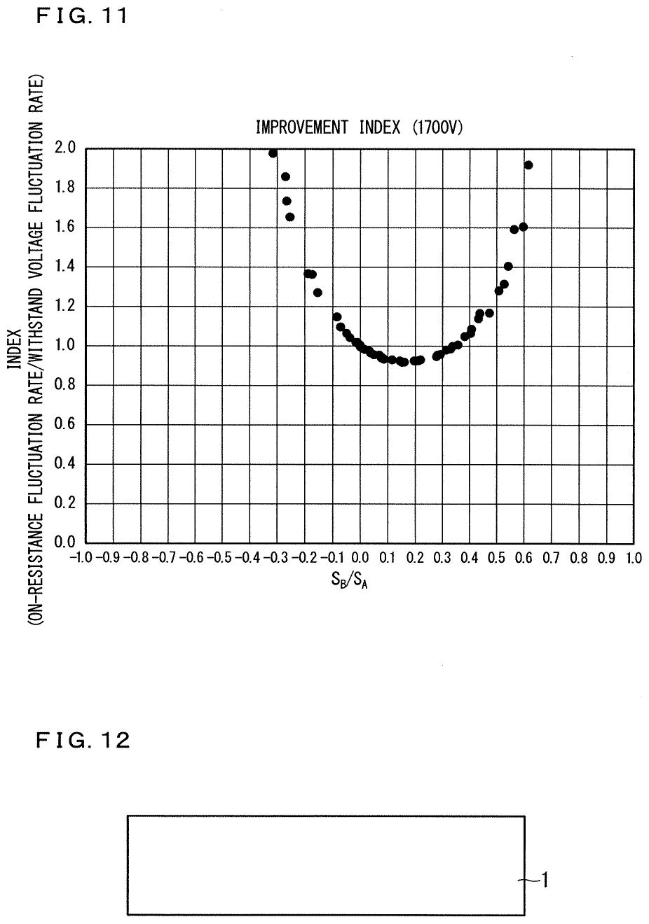

FIG. 9 is a view indicating a boundary at which both improvement in the withstand voltage and reduction in the on-resistance of a 600 V-class device are achieved when the thickness of the drift layer is set at 5.5 μm. FIG. 10 is a view indicating a boundary at which both improvement in the withstand voltage and reduction in the on-resistance of a 1200 V-class device are achieved when the thickness of the drift layer is set at 10 μm. FIG. 11 is a view indicating a boundary at which both improvement in the withstand voltage and reduction in the on-resistance of a 1700 V-class device are achieved when the thickness of the drift layer is set at 15 μm. In FIGS. 9, 10, and 11, a vertical axis represents an index (an on-resistance fluctuation rate/a withstand voltage fluctuation rate), and a horizontal axis represents S_{B}/S_{A}.

In FIGS. 9, 10, and 11, S_{A} indicates an area (reference value) of a triangle as indicated in FIG. 28, and S_{B} indicates an increase (S_{A}+S_{B}−S_{A}) from the reference value of the withstand voltage value having the arcuate arc as indicated in FIG. 6. S_{B} is an increase in the withstand voltage value (an increase in the withstand voltage) in the electric field distribution that is a limit at which the trade-off relationship between the withstand voltage and the on-resistance is improved as compared with the case (comparative example) indicated in FIG. 28 in the present preferred embodiment.

In addition, the withstand voltage fluctuation rate is defined by the withstand voltage of the structure/S_{A}, and the on-resistance fluctuation rate is defined by the on-resistance of the structure/the on-resistance of the structure of the comparative example.

In other words, a condition under which an index (the on-resistance fluctuation rate/the withstand voltage fluctuation rate) becomes 1.0 is a state in which fluctuation of the withstand voltage and fluctuation of the on-resistance are effectively balanced, and indicates that there is a trade-off relationship between the withstand voltage and the on-resistance, which is the same as that in the comparative example of S_{B}/S_{A}=0 (S_{B}=0). If the index (the on-resistance fluctuation rate/the withstand voltage fluctuation rate) is greater than 1, it indicates that the trade-off is deteriorated, and if the index (the on-resistance fluctuation rate/the withstand voltage fluctuation rate) is equal to or less than 1, it indicates that the trade-off is improved.

In FIGS. 9, 10, and 11, the above-described index indicates a concave characteristic as a whole, which becomes 1 when S_{B}/S_{A}=0. The inventors have confirmed that a range in which the above-described index is equal to or less than 1 is limited and is limited to a range of approximately S_{B}/S_{A}≤0.32 (conditional expression 1). Specifically, the above-described index becomes equal to or less than 1 when S_{B}/S_{A} is equal to or greater than 0 and equal to or less than 0.32, becomes equal to or less than 0.93 when S_{B}/S_{A} is equal to or greater than 0.11 and equal to or less than 0.21, and becomes 0.922 when S_{B}/S_{A} is 0.16.

In a case where the conditional expression 1 is not satisfied, the trade-off cannot be improved from the case of the comparative example, and in a case where the conditional expression 1 is satisfied, the trade-off between the on-resistance and the withstand voltage can be improved as compared with the case of the comparative example by appropriately designing.

In the present preferred embodiment, a step-type region is formed to satisfy this condition.

As a condition for forming such a structure, it is effective that the impurity concentration of the n− drift layer 3a is lower than the impurity concentration of the n− drift layer 3b and lower than the impurity concentration of the n− drift layer 3 in the comparative example. As a specific impurity concentration, by setting the impurity concentration of the n− drift layer 3a and the n− drift layer 3b at equal to or less than 5×10¹⁶/cm³ at any position, setting the impurity concentration of the n− drift layer 3a on the source side at equal to or greater than 1×10¹⁵/cm³ and equal to or less than 2×10¹⁶/cm³, and setting the impurity concentration of the n− drift layer 3b on the drain side at equal to or greater than 5×10¹⁵/cm³ and equal to or less than 5×10¹⁶/cm³, the above-described condition can be efficiently satisfied.

In addition, considering manufacturing variations, it is effective to manufacture the device so that S_{B}/S_{A} is always between S_{B}/S_{A}=0 and S_{B}/S_{A}=0.32. Thus, if the range is narrowed to 0.11≤S_{B}/S_{A}≤0.21 or concentration design is performed around S_{B}/S_{A}=0.16, a possibility of improving the trade-off can be increased. However, even if S_{B}/S_{A} varies, if part of S_{B}/S_{A} satisfies the conditional expression 1, improvement of the trade-off is achieved.

### <Method of Manufacturing Semiconductor Device>

Next, a method of manufacturing a semiconductor device according to the present preferred embodiment will be described with reference to FIGS. 12, 13, 14, and 15. Here, FIGS. 12, 13, 14, and 15 are views illustrating an example of the method of manufacturing the semiconductor device according to the present preferred embodiment.

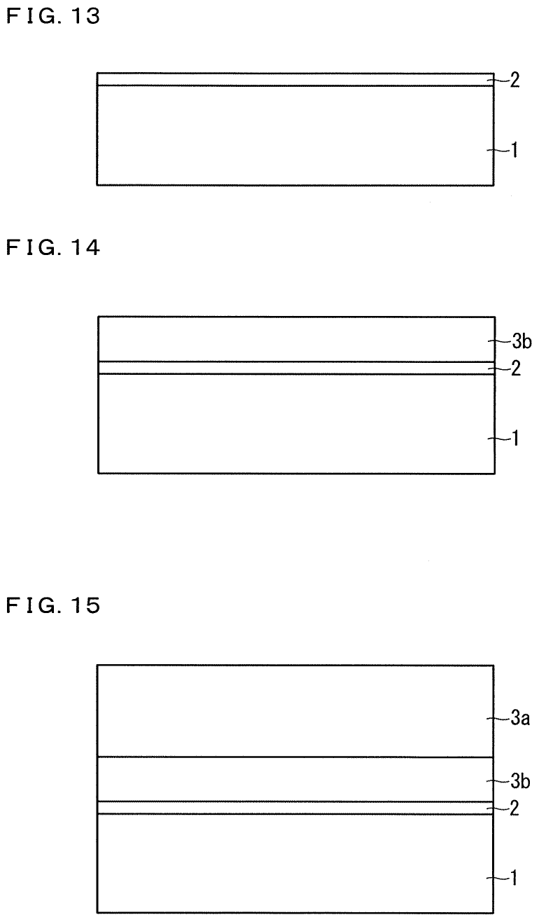

FIG. 12 illustrates a state in which nothing is formed on the n+ semiconductor substrate 1. In this state, the n+ buffer layer 2 is formed at an appropriate concentration on the upper surface side of the n+ semiconductor substrate 1 using means such as epitaxial growth (see FIG. 13).

Next, the n− drift layer 3b is formed using means such as epitaxial growth while changing a concentration of a gas that is a source of the N-type impurities so as to have an appropriate concentration and concentration gradient (see FIG. 14).

Furthermore, the n− drift layer 3a is formed using a method such as epitaxial growth while changing a gas flow rate, or the like, so as to have an appropriate concentration (see FIG. 15).

The structure illustrated in FIG. 3 can be manufactured by forming structures on the upper surface and the lower surface using the structure illustrated in FIG. 15. Note that the processes in and after FIG. 15 can be performed using a general semiconductor device forming process, and thus, details will be omitted.

As described above, in the present preferred embodiment, by forming the semiconductor device so as to satisfy the condition of the electric field distribution found by the inventors, the withstand voltage can be increased even with the same thickness of the drift layer, and the trade-off relationship between the withstand voltage and the on-resistance can be improved. In other words, the withstand voltage can be increased by increasing the withstand voltage area without changing the critical electric field intensity, and the trade-off relationship between the withstand voltage and the on-resistance can be improved.

### Second Preferred Embodiment

A semiconductor device according to the present preferred embodiment will be described. Note that, in the following description, components similar to the components described in the preferred embodiment described above are denoted by the same reference numerals, and detailed description thereof will be omitted as appropriate.

### <Configuration of Semiconductor Device>

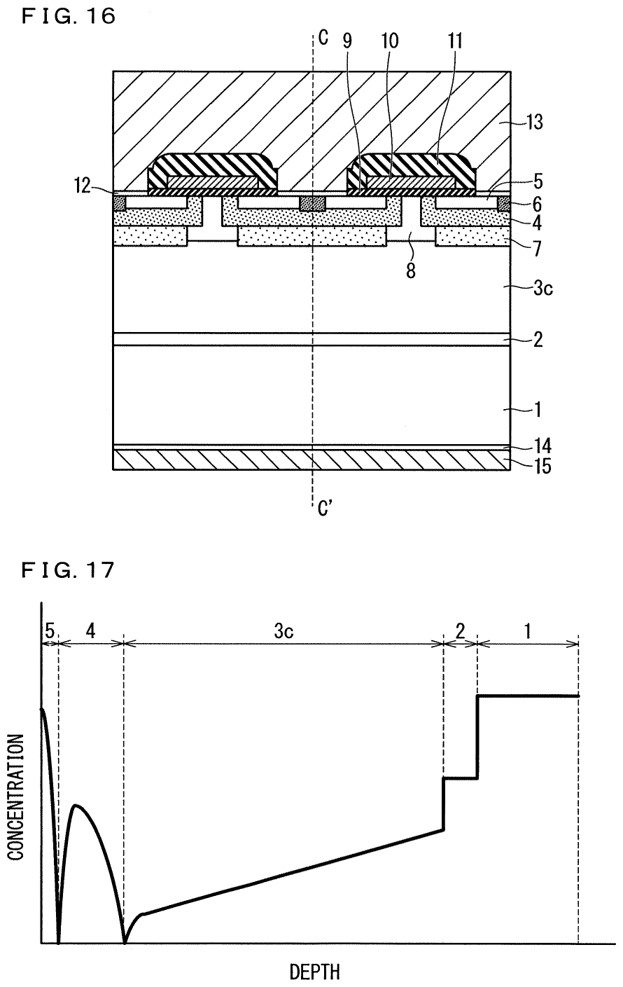

FIG. 16 is a cross-sectional view illustrating a modification of the A-A′ cross section in FIG. 2 according to the present preferred embodiment. FIG. 17 is a view illustrating an example of an impurity concentration profile along a C-C′ cross section in FIG. 16. In FIG. 17, a vertical axis represents an impurity concentration, and a horizontal axis represents a depth.

A method of manufacturing the structure illustrated in FIG. 16 is similar to that illustrated in the first preferred embodiment except for a portion of the n− drift layer 3c, and thus, details will be omitted.

In the present preferred embodiment, the n− drift layer 3c is formed in a portion where the n− drift layer 3a and the n− drift layer 3b are formed in FIG. 3.

As indicated in FIG. 17, the n− drift layer 3c has constant inclination of the impurity concentration. In the n− drift layer 3c, the impurity concentration on the source side is low, and the impurity concentration gradually (linearly) increases toward the drain side.

The electric field distribution formed by the concentration gradient of the n− drift layer 3c is formed so as to fall within S_{B} indicated in FIG. 6 as an example. Specifically, an inclination angle of an oblique side of S_{A} in the view indicating the electric field distribution is appropriately adjusted by controlling the concentration gradient of the n− drift layer 3c, and is formed so as to satisfy the conditional expression 1 described above.

According to the present preferred embodiment, the configuration as described above is employed, and thus, the withstand voltage can be increased even with the same thickness of the drift layer, and the trade-off relationship between the withstand voltage and the on-resistance can be improved. In other words, the withstand voltage can be increased by increasing the withstand voltage area without changing the critical electric field intensity, and the trade-off relationship between the withstand voltage and the on-resistance can be improved.

As the impurity concentration of the n− drift layer 3c, the impurity concentration is preferably equal to or less than 5×10¹⁶/cm³ at any position, the impurity concentration of the n− drift layer 3c on the source side is preferably equal to or greater than 1×10¹⁵/cm³ and equal to or less than 2×10¹⁶/cm³, and the impurity concentration of the n− drift layer 3c on the drain side is preferably equal to or greater than 5×10¹⁵/cm³ and equal to or less than 5×10¹⁶/cm³.

### Third Preferred Embodiment

A semiconductor device according to the present preferred embodiment will be described. Note that, in the following description, components similar to the components described in the preferred embodiment described above are denoted by the same reference numerals, and detailed description thereof will be omitted as appropriate.

### <Configuration of Semiconductor Device>

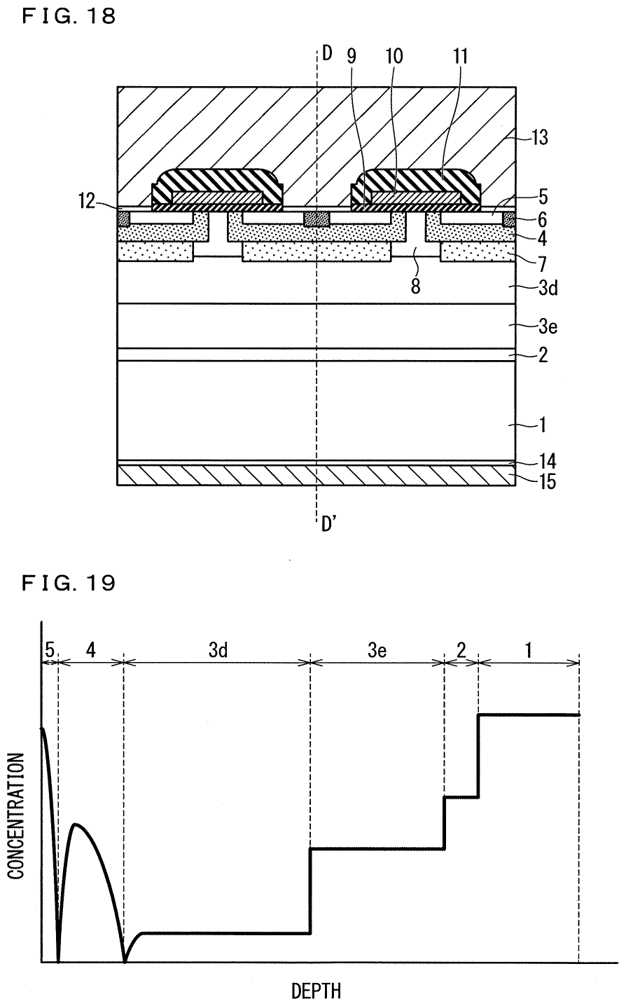

FIG. 18 is a cross-sectional view illustrating a modification of the A-A′ cross section in FIG. 2 according to the present preferred embodiment. FIG. 19 is a view indicating an example of an impurity concentration profile along a D-D′ cross section in FIG. 18. In FIG. 19, a vertical axis represents an impurity concentration, and a horizontal axis represents a depth.

The method of manufacturing the structure illustrated in FIG. 18 is similar to that illustrated in the first preferred embodiment except for portions of the n− drift layer 3d and the n− drift layer 3e, and thus, details will be omitted.

In the present preferred embodiment, the n− drift layer 3d and the n− drift layer 3e are formed in a portion where the n− drift layer 3a and the n− drift layer 3b are formed in FIG. 3.

As indicated in FIG. 19, each of the n− drift layer 3d and the n− drift layer 3e has constant impurity concentration, and the impurity concentration of the n− drift layer 3e on the lower layer side is higher than the impurity concentration of the n− drift layer 3d on the upper layer side. In other words, the impurity concentration of the n− drift layer increases stepwise from the source side toward the drain side.

The electric field distribution formed by the n− drift layer 3d and the n− drift layer 3e is formed so as to fall within S_{B} indicated in FIG. 6 as an example. Specifically, an inclination angle of an oblique side of S_{A} in the view indicating the electric field distribution is appropriately adjusted by controlling the concentration gradient of the n− drift layer 3d and the n− drift layer 3e, and is formed so as to satisfy the conditional expression 1 described above.

According to the present preferred embodiment, the impurity concentration of the n− drift layer is constant in the portion of the surface where the MOS structure is formed.

According to the present preferred embodiment, the configuration as described above is employed, and thus, the withstand voltage can be increased even with the same thickness of the drift layer, and the trade-off relationship between the withstand voltage and the on-resistance can be improved. In other words, the withstand voltage can be increased by increasing the withstand voltage area without changing the critical electric field intensity, and the trade-off relationship between the withstand voltage and the on-resistance can be improved.

In addition, as indicated in FIG. 19, in the present preferred embodiment, the impurity concentration is constant in the portion where a MOS structure (such as the p-channel doped layer 4 and the n+ source layer 5) is formed on the surface, so that it is possible to reduce fluctuation in a threshold voltage or the on-resistance due to influence of the concentration variation in manufacturing.

As the impurity concentration of the n− drift layer 3d and the n− drift layer 3e, the impurity concentration is preferably equal to or less than 5×10¹⁶/cm³ at any position, the impurity concentration of the n− drift layer 3d on the source side is preferably equal to or greater than 1×10¹⁵/cm³ and equal to or less than 2×10¹⁶/cm³, and the impurity concentration of the n− drift layer 3e on the drain side is preferably equal to or greater than 5×10¹⁵/cm³ and equal to or less than 5×10¹⁶/cm³.

### Fourth Preferred Embodiment

A semiconductor device according to the present preferred embodiment will be described. Note that, in the following description, components similar to the components described in the preferred embodiment described above are denoted by the same reference numerals, and detailed description thereof will be omitted as appropriate.

### <Configuration of Semiconductor Device>

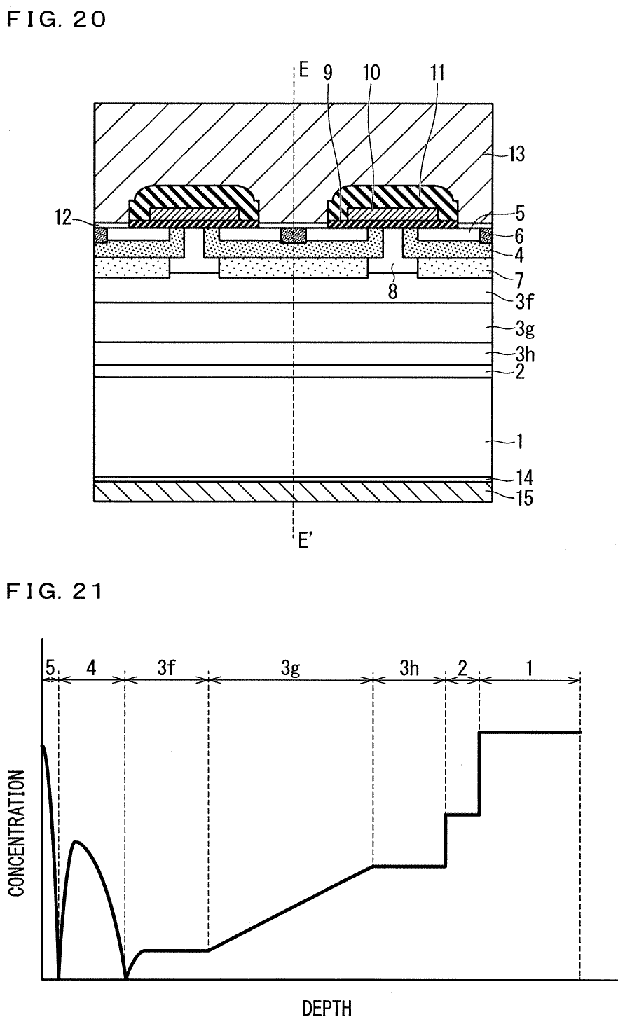

FIG. 20 is a cross-sectional view illustrating a modification of the A-A′ cross section in FIG. 2 according to the present preferred embodiment. FIG. 21 is a view indicating an example of an impurity concentration profile along an E-E′ cross section in FIG. 20. In FIG. 21, a vertical axis represents an impurity concentration, and a horizontal axis represents a depth.

A method of manufacturing the structure illustrated in FIG. 20 is similar to that of the first preferred embodiment except for portions of the n− drift layer 3f, the n− drift layer 3g, and the n− drift layer 3h, and thus, details will be omitted.

In the present preferred embodiment, the n− drift layer 3f, the n− drift layer 3g, and the n− drift layer 3h are formed in a portion where the n− drift layer 3a and the n− drift layer 3b are formed in FIG. 3.

As indicated in FIG. 21, each of the n− drift layer 3f and the n− drift layer 3h has a constant impurity concentration, and the impurity concentration of the n− drift layer 3h on the lower layer side is higher than the impurity concentration of the n− drift layer 3f on the upper layer side. The n− drift layer 3g is formed between the n− drift layer 3f and the n− drift layer 3h, and has an impurity concentration that continuously changes from the impurity concentration of the n− drift layer 3f to the impurity concentration of the n− drift layer 3h.

The electric field distribution formed by the n− drift layer 3f, the n− drift layer 3g, and the n− drift layer 3h is formed so as to fall within S_{B} indicated in FIG. 6 as an example. Specifically, an inclination angle of an oblique side of S_{A} in the view indicating the electric field distribution is appropriately adjusted by controlling the concentration gradients of the n− drift layer 3f, the n− drift layer 3g, and the n− drift layer 3h, and is formed so as to satisfy the conditional expression 1 described above.

According to the present preferred embodiment, the impurity concentration of the n− drift layer is constant in the portion of the surface where the MOS structure is formed.

According to the present preferred embodiment, the configuration as described above is employed, and thus, the withstand voltage can be increased even with the same thickness of the drift layer, and the trade-off relationship between the withstand voltage and the on-resistance can be improved. In other words, the withstand voltage can be increased by increasing the withstand voltage area without changing the critical electric field intensity, and the trade-off relationship between the withstand voltage and the on-resistance can be improved.

In addition, as indicated in FIG. 21, in the present preferred embodiment, the impurity concentration is constant in the portion where the MOS structure is formed on the surface, so that it is possible to reduce fluctuation of a threshold voltage or the on-resistance due to influence of the concentration variation in manufacturing.

As the impurity concentration of the n− drift layer 3f, the n− drift layer 3g, and the n− drift layer 3h, the impurity concentration is preferably equal to or less than 5×10¹⁶/cm³ at any position, the impurity concentration of the n− drift layer 3f on the source side is preferably equal to or greater than 1×10¹⁵/cm³ and equal to or less than 2×10¹⁶/cm³, and the impurity concentration of the n− drift layer 3h on the drain side is preferably equal to or greater than 5×10¹⁵/cm³ and equal to or less than 5×10¹⁶/cm³.

### Fifth Preferred Embodiment

A semiconductor device according to the present preferred embodiment will be described. Note that, in the following description, components similar to the components described in the preferred embodiment described above are denoted by the same reference numerals, and detailed description thereof will be omitted as appropriate.

### <Configuration of Semiconductor Device>

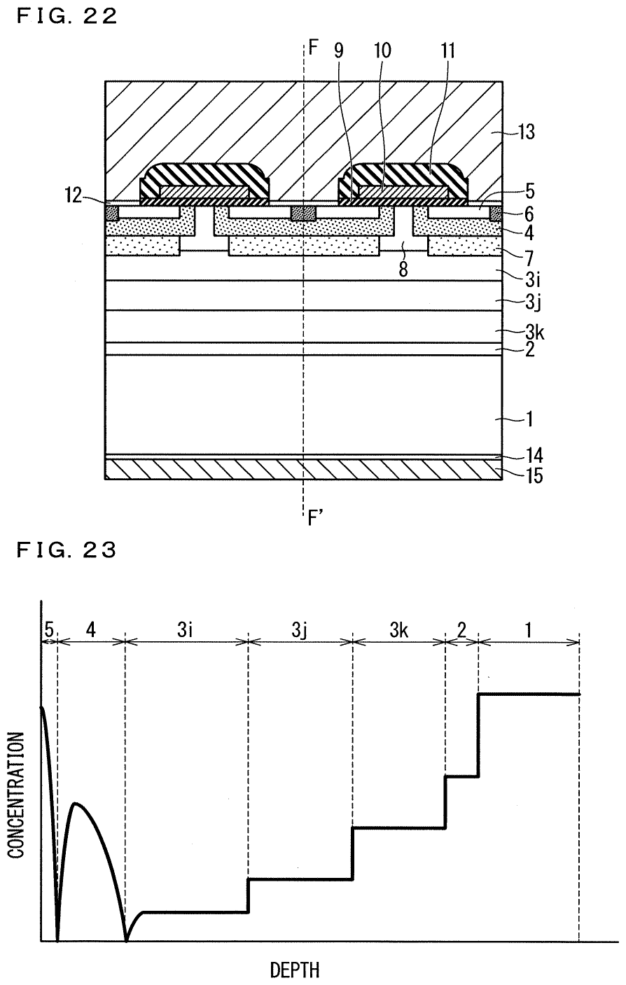

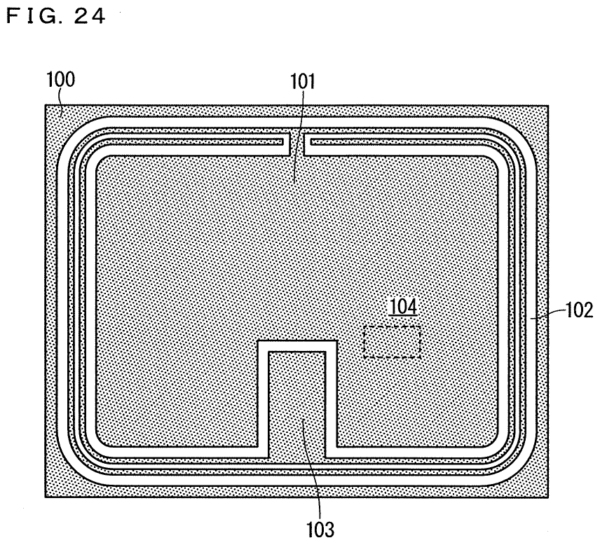

FIG. 22 is a cross-sectional view illustrating a modification of the A-A′ cross section in FIG. 2 according to the present preferred embodiment. FIG. 23 is a view indicating an example of an impurity concentration profile along an F-F′ cross section in FIG. 22. In FIG. 23, a vertical axis represents an impurity concentration, and a horizontal axis represents a depth.

A method of manufacturing the structure illustrated in FIG. 22 is similar to that illustrated in the first preferred embodiment except for portions of the n− drift layer 3i, the n− drift layer 3j, and the n− drift layer 3k, and thus, details will be omitted.

In the present preferred embodiment, an n− drift layer 3i, an n− drift layer 3j, and an n− drift layer 3k are formed in a portion where the n− drift layer 3a and the n− drift layer 3b are formed in FIG. 3.

As indicated in FIG. 23, each of the n− drift layer 3i, the n− drift layer 3j, and the n− drift layer 3k has a constant impurity concentration, and the impurity concentration of the n− drift layer 3k on the lower layer side is higher than the impurity concentration of the n− drift layer 3i on the upper layer side. The n− drift layer 3j is formed between the n− drift layer 3i and the n− drift layer 3k, and has an impurity concentration between the impurity concentration of the n− drift layer 3i and the impurity concentration of the n− drift layer 3k.

The electric field distribution formed by the n− drift layer 3i, the n− drift layer 3j, and the n− drift layer 3k is formed so as to fall within S_{B} indicated in FIG. 6 as an example. Specifically, an inclination angle of an oblique side of S_{A} in the view indicating the electric field distribution is appropriately adjusted by controlling concentration gradients of the n− drift layer 3i, the n− drift layer 3j, and the n− drift layer 3k, and is formed to satisfy the conditional expression 1 described above.

According to the present preferred embodiment, the impurity concentration of the n− drift layer is constant in the portion of the surface where the MOS structure is formed.

According to the present preferred embodiment, the configuration as described above is employed, and thus, the withstand voltage can be increased even with the same thickness of the drift layer, and the trade-off relationship between the withstand voltage and the on-resistance can be improved. In other words, the withstand voltage can be increased by increasing the withstand voltage area without changing the critical electric field intensity, and the trade-off relationship between the withstand voltage and the on-resistance can be improved.

In addition, as indicated in FIG. 23, in the present preferred embodiment, the impurity concentration is constant in the portion where the MOS structure is formed on the surface, so that it is possible to reduce fluctuation of the threshold voltage or the on-resistance due to influence of the concentration variation in manufacturing.

As the impurity concentration of the n− drift layer 3i, the n− drift layer 3j, and the n− drift layer 3k, the impurity concentration is preferably equal to or less than 5×10¹⁶/cm³ at any position, the impurity concentration of the n− drift layer 3i on the source side is preferably equal to or greater than 1×10¹⁵/cm³ and equal to or less than 2×10¹⁶/cm³, the impurity concentration of the n− drift layer 3k on the drain side is preferably equal to or greater than 5×10¹⁵/cm³ and equal to or less than 5×10¹⁶/cm³, and the impurity concentration of the n− drift layer 3j on the drain side is preferably between the impurity concentration of the n− drift layer 3i and the impurity concentration of the n− drift layer 3k.

### Effects to be Exerted by the Plurality of Preferred Embodiments Described Above

Next, an example of effects to be exerted by the plurality of preferred embodiments described above will be described. Note that, in the following description, the effects will be described based on the specific configurations exemplified in the plurality of preferred embodiments described above, but may be replaced with other specific configurations exemplified in the present specification as long as similar effects are exerted. In other words, in the following description, for convenience, only one of the associated specific configurations may be described as a representative, but the specific configuration described as a representative may be replaced with another specific configuration associated.

Furthermore, the specific configurations may be replaced across the plurality of preferred embodiments. In other words, the same effects may be exerted by combining the respective configurations exemplified in different preferred embodiments.

According to the preferred embodiment described above, a semiconductor device includes a drift layer of a first conductivity type, a channel layer of a second conductivity type that is above the drift layer, a source layer of the first conductivity type that is above the channel layer, a gate electrode 10 facing the channel layer sandwiched between the drift layer and the source layer via a gate insulating film 9, a source electrode 13 connected to the source layer, and a drain electrode 15 on a lower surface side of the drift layer. Here, the drift layer corresponds to, for example, the n− drift layer 3a, the n− drift layer 3b, the n− drift layer 3c, the n− drift layer 3d, the n− drift layer 3e, the n− drift layer 3f, the n− drift layer 3g, the n− drift layer 3h, the n− drift layer 3i, the n− drift layer 3j, the n− drift layer 3k, or the like. Further, the channel layer corresponds to, for example, the p-channel doped layer 4. Further, the source layer corresponds to, for example, the n+ source layer 5. Still further, the impurity concentration of the drift layer is different in the drift layer. In a case where the integral value of the electric field applied to the drift layer is defined as a withstand voltage value and the integral value of the electric field in a case where the impurity concentration of the drift layer is constant in the drift layer is defined as a reference value, (the withstand voltage value−the reference value)/the reference value is equal to or greater than 0 and equal to or less than 0.32.

According to such a configuration, an increase in the withstand voltage value/the reference value is equal to or greater than 0 and equal to or less than 0.32, so that the trade-off relationship between the withstand voltage and the on-resistance of the semiconductor device can be improved as compared with the case where the impurity concentration of the drift layer is constant.

Note that, even in a case where another configuration exemplified in the present specification is appropriately added to the above configuration, that is, even in a case where another configuration not mentioned as the above-described configuration in the present specification is appropriately added, similar effects can be exerted.

Further, according to the preferred embodiments described above, (the withstand voltage value−the reference value)/the reference value is equal to or greater than 0.11 and equal to or less than 0.21. According to such a configuration, even in a case where manufacturing variations occur, it is easy to implement concentration design of the drift layer that improves the trade-off.

Further, according to the preferred embodiments described above, (the withstand voltage value−the reference value)/the reference value is 0.16. According to such a configuration, even in a case where manufacturing variations occur, it is easy to implement concentration design of the drift layer that improves the trade-off.

Further, according to the preferred embodiments described above, the electric field intensity applied to the drift layer corresponding to the withstand voltage value is higher in the entire region of the drift layer than the electric field intensity applied to the drift layer corresponding to the reference value. According to such a configuration, the withstand voltage value is increased, so that the withstand voltage of the semiconductor device can be increased.

According to the preferred embodiments described above, the drift layer includes a first region (n− drift layer 3a) and a second region (n− drift layer 3b) that is a region closer to the drain electrode 15 than the first region. Further, a first change rate that is a change rate of the electric field applied to the n− drift layer 3a is lower than a second change rate that is a change rate of the electric field applied to the n− drift layer 3b. According to such a configuration, the arcuate arc of the withstand voltage area protrudes upward, and the withstand voltage value increases. It is therefore possible to increase the withstand voltage of the semiconductor device.

According to the preferred embodiments described above, a change rate of the electric field applied to the n− drift layer 3 corresponding to the reference value is set as a reference change rate. The first change rate is lower than the reference change rate, and the second change rate is higher than the reference change rate. According to such a configuration, the arcuate arc of the withstand voltage area protrudes upward, and the withstand voltage value increases. It is therefore possible to increase the withstand voltage of the semiconductor device.

According to the preferred embodiments described above, the drift layer is formed of silicon carbide. The drift layer has an impurity concentration of equal to or less than 5×10¹⁶/cm³ in the entire region of the drift layer. According to such a configuration, an increase in the withstand voltage value/the reference value is equal to or greater than 0 and equal to or less than 0.32, so that the trade-off relationship between the withstand voltage and the on-resistance of the semiconductor device can be improved as compared with the case where the impurity concentration of the drift layer is constant.

According to the preferred embodiments described above, the drift layer has a first region (the n− drift layer 3a, the n− drift layer 3d, the n− drift layer 3f, the n− drift layer 3g, the n− drift layer 3i, the n− drift layer 3j) and a second region (the n− drift layer 3b, the n− drift layer 3e, the n− drift layer 3h, the n− drift layer 3k) that is a region closer to the drain electrode 15 than the first region. The impurity concentration of the drift layer in the first region is equal to or lower than the impurity concentration of the drift layer in the second region. According to such a configuration, an increase in the withstand voltage value/the reference value is equal to or greater than 0 and equal to or less than 0.32, so that the trade-off relationship between the withstand voltage and the on-resistance of the semiconductor device can be improved as compared with the case where the impurity concentration of the drift layer is constant.

According to the preferred embodiments described above, the drift layer in the first region (the n− drift layer 3a, the n− drift layer 3d, the n− drift layer 3f, the n− drift layer 3i) has an impurity concentration of equal to or greater than 1×10¹⁵/cm³ and equal to or less than 2×10¹⁶/cm³, and the drift layer in the second region (the n− drift layer 3b, the n− drift layer 3e, the n− drift layer 3h, the n− drift layer 3k) has an impurity concentration of equal to or greater than 5×10¹⁵/cm³ and equal to or less than 5×10¹⁶/cm³. According to such a configuration, an increase in the withstand voltage value/the reference value is equal to or greater than 0 and equal to or less than 0.32, so that the trade-off relationship between the withstand voltage and the on-resistance of the semiconductor device can be improved as compared with the case where the impurity concentration of the drift layer is constant.

According to the preferred embodiments described above, the impurity concentration of the n− drift layer 3c linearly increases from the source electrode 13 toward the drain electrode 15. According to such a configuration, the drift layer having the impurity concentration satisfying the condition can be easily formed.

According to the preferred embodiments described above, the impurity concentration of the drift layer increases stepwise from the first region (the n− drift layer 3d, the n− drift layer 3f, the n− drift layer 3i, the n− drift layer 3j) toward the second region (the n− drift layer 3e, the n− drift layer 3h, the n− drift layer 3k). According to such a configuration, the drift layer having the impurity concentration satisfying the condition can be easily formed.

According to the preferred embodiments described above, the impurity concentration of the drift layer in one of the first region (the n− drift layer 3a, the n− drift layer 3d, the n− drift layer 3f, the n− drift layer 3g, the n− drift layer 3i, the n− drift layer 3j) and the second region (the n− drift layer 3b, the n− drift layer 3e, the n− drift layer 3h, the n− drift layer 3k) does not change, and the impurity concentration of the drift layer in the other region changes. According to such a configuration, the drift layer having the impurity concentration satisfying the condition can be easily formed.

Further, according to the preferred embodiments described above, the impurity concentration of the drift layer (the n− drift layer 3d, the n− drift layer 3f, the n− drift layer 3i) on the side closer to the source electrode 13 does not change. According to such a configuration, it is possible to reduce fluctuation of the threshold voltage or the on-resistance due to influence of the concentration variation in manufacturing.

According to the preferred embodiments described above, the p-channel doped layer 4 and the n+ source layer 5 are provided in the drift layer (the n− drift layer 3d, the n− drift layer 3f, the n− drift layer 3i) on the side closer to the source electrode 13 where the impurity concentration does not change. According to such a configuration, it is possible to reduce fluctuation of the threshold voltage or the on-resistance due to influence of the concentration variation in manufacturing.

### Modifications of the Plurality of Preferred Embodiments Described Above

In the plurality of preferred embodiments described above, the concentration inclination of the impurity concentration, the number or width of the step-type steps, or the like, is indicated, but these are merely examples, and as long as the structure satisfies the electric field distribution in the plurality of preferred embodiments described above, the trade-off relationship between the withstand voltage and the on-resistance can be improved with the concentration inclination or the number or width of the step-type steps, or the like, other than those as indicated.

In addition, in the plurality of preferred embodiments described above, the planar type semiconductor device has been described, but a trench type semiconductor device may be used.

In the plurality of preferred embodiments described above, a material, a dimension, a shape, a relative arrangement relationship, an implementation condition, or the like, of each component may also be described, but these are one example in all aspects and are not restrictive.

Thus, innumerable modifications and equivalents in which no examples are indicated are assumed within the scope of the technology disclosed in the present specification. For example, a case where at least one component is modified, added, or omitted, and a case where at least one component in at least one preferred embodiment is extracted and combined with a component in another preferred embodiment are included.

In addition, in at least one preferred embodiment described above, in a case where a material name, or the like, is described without being particularly specified, unless inconsistency arises, the material includes other additives, for example, an alloy, or the like.

In addition, unless inconsistency arises, in a case where it is described in the above-described preferred embodiments that “one” component is provided, “one or more” components may be provided.

Furthermore, each component in the preferred embodiments described above is a conceptual unit, and the scope of the technology disclosed in the present specification includes a case where one component includes a plurality of structures, a case where one component corresponds to part of a certain structure, and a case where a plurality of components is included in one structure.

In addition, each component in the preferred embodiments described above includes a structure having another structure or shape as long as the same function is exhibited.

In addition, the description herein is referred to for all purposes related to the present technology, and none of them is recognized as related art.

Hereinafter, various aspects of the present disclosure will be collectively described as appendixes.

### Appendix 1

A semiconductor device comprising:
a drift layer of a first conductivity type;
a channel layer of a second conductivity type that is above the drift layer;
a source layer of the first conductivity type that is above the channel layer;
a gate electrode facing the channel layer sandwiched between the drift layer and the source layer via a gate insulating film;
a source electrode connected to the source layer; and
a drain electrode on a lower surface side of the drift layer, wherein
an impurity concentration of the drift layer is different in the drift layer, and
in a case where an integral value of an electric field applied to the drift layer is set as a withstand voltage value and an integral value of an electric field in a case where the impurity concentration of the drift layer is constant in the drift layer is set as a reference value, (the withstand voltage value−the reference value)/the reference value is equal to or greater than 0 and equal to or less than 0.32.

### Appendix 2

The semiconductor device according to Appendix 1, wherein (the withstand voltage value−the reference value)/the reference value is equal to or greater than 0.11 and equal to or less than 0.21.

### Appendix 3

The semiconductor device according to Appendix 1 or 2, wherein (the withstand voltage value−the reference value)/the reference value is 0.16.

### Appendix 4

The semiconductor device according to any one of Appendixes 1 to 3, wherein electric field intensity applied to the drift layer corresponding to the withstand voltage value is higher in an entire region of the drift layer than electric field intensity applied to the drift layer corresponding to the reference value.

### Appendix 5

The semiconductor device according to any one of Appendixes 1 to 4, wherein
the drift layer includes a first region and a second region that is a region closer to the drain electrode than the first region, and
a first change rate that is a change rate of an electric field applied to the drift layer in the first region is lower than a second change rate that is a change rate of an electric field applied to the drift layer in the second region.

### Appendix 6

The semiconductor device according to Appendix 5, wherein
a change rate of an electric field applied to the drift layer corresponding to the reference value is set as a reference change rate, and
the first change rate is lower than the reference change rate, and the second change rate is higher than the reference change rate.

### Appendix 7

The semiconductor device according to any one of Appendixes 1 to 6, wherein
the drift layer is formed of silicon carbide, and
an impurity concentration of the drift layer is equal to or less than 5×10¹⁶/cm³ in an entire region of the drift layer.

### Appendix 8

The semiconductor device according to any one of Appendixes 1 to 7, wherein
the drift layer includes a first region and a second region that is a region closer to the drain electrode than the first region, and
an impurity concentration of the drift layer in the first region is equal to or less than an impurity concentration of the drift layer in the second region.

### Appendix 9

The semiconductor device according to Appendix 8, wherein an impurity concentration of the drift layer in the first region is equal to or greater than 1×10¹⁵/cm³ and equal to or less than 2×10¹⁶/cm³, and an impurity concentration of the drift layer in the second region is equal to or greater than 5×10¹⁵/cm³ and equal to or less than 5×10¹⁶/cm³.

### Appendix 10

The semiconductor device according to Appendix 8 or 9, wherein an impurity concentration of the drift layer linearly increases from the source electrode toward the drain electrode.

### Appendix 11

The semiconductor device according to Appendix 8 or 9, wherein an impurity concentration of the drift layer increases stepwise from the first region toward the second region.

### Appendix 12

The semiconductor device according to Appendix 8 or 9, wherein an impurity concentration of the drift layer in one of the first region and the second region does not change, and an impurity concentration of the drift layer in the other region changes.

### Appendix 13

The semiconductor device according to Appendix 8 or 9, wherein an impurity concentration of the drift layer on a side close to the source electrode does not change.

### Appendix 14

The semiconductor device according to Appendix 13, wherein the channel layer and the source layer are provided in the drift layer on a side close to the source electrode where an impurity concentration does not change.

While the disclosure has been shown and described in detail, the foregoing description is in all aspects illustrative and not restrictive. It is therefore understood that numerous modifications and variations can be devised.

What is claimed is:

1. A semiconductor device comprising:
a drift layer of a first conductivity type;
a channel layer of a second conductivity type that is above the drift layer;
a source layer of the first conductivity type that is above the channel layer;
a gate electrode facing the channel layer sandwiched between the drift layer and the source layer via a gate insulating film;
a source electrode connected to the source layer; and
a drain electrode on a lower surface side of the drift layer, wherein
an impurity concentration of the drift layer is different in the drift layer, and
in a case where an integral value of an electric field applied to the drift layer is set as a withstand voltage value and an integral value of an electric field in a case where the impurity concentration of the drift layer is constant in the drift layer is set as a reference value, (the withstand voltage value−the reference value)/the reference value is equal to or greater than 0 and equal to or less than 0.32.

2. The semiconductor device according to claim 1, wherein (the withstand voltage value−the reference value)/the reference value is equal to or greater than 0.11 and equal to or less than 0.21.

3. The semiconductor device according to claim 1, wherein (the withstand voltage value−the reference value)/the reference value is 0.16.

4. The semiconductor device according to claim 1, wherein electric field intensity applied to the drift layer corresponding to the withstand voltage value is higher in an entire region of the drift layer than electric field intensity applied to the drift layer corresponding to the reference value.

5. The semiconductor device according to claim 1, wherein
the drift layer includes a first region and a second region that is a region closer to the drain electrode than the first region, and
a first change rate that is a change rate of an electric field applied to the drift layer in the first region is lower than a second change rate that is a change rate of an electric field applied to the drift layer in the second region.

6. The semiconductor device according to claim 5, wherein
a change rate of an electric field applied to the drift layer corresponding to the reference value is set as a reference change rate, and
the first change rate is lower than the reference change rate, and the second change rate is higher than the reference change rate.

7. The semiconductor device according to claim 1, wherein
the drift layer is formed of silicon carbide, and
an impurity concentration of the drift layer is equal to or less than 5×10¹⁶/cm³ in an entire region of the drift layer.

8. The semiconductor device according to claim 1, wherein
the drift layer includes a first region and a second region that is a region closer to the drain electrode than the first region, and
an impurity concentration of the drift layer in the first region is equal to or less than an impurity concentration of the drift layer in the second region.

9. The semiconductor device according to claim 8, wherein an impurity concentration of the drift layer in the first region is equal to or greater than 1×10¹⁵/cm³ and equal to or less than 2×10¹⁶/cm³, and an impurity concentration of the drift layer in the second region is equal to or greater than 5×10¹⁵/cm³ and equal to or less than 5×10¹⁶/cm³.

10. The semiconductor device according to claim 8, wherein an impurity concentration of the drift layer linearly increases from the source electrode toward the drain electrode.

11. The semiconductor device according to claim 8, wherein an impurity concentration of the drift layer increases stepwise from the first region toward the second region.

12. The semiconductor device according to claim 8, wherein an impurity concentration of the drift layer in one of the first region and the second region does not change, and an impurity concentration of the drift layer in the other region changes.

13. The semiconductor device according to claim 8, wherein an impurity concentration of the drift layer on a side close to the source electrode does not change.

14. The semiconductor device according to claim 13, wherein the channel layer and the source layer are provided in the drift layer on a side close to the source electrode where an impurity concentration does not change.
